(19) United States
(12) Patent Application Publication
(10) Pub. No.: US 2013/0181210 A1
(43) Pub. Date: Jul. 18, 2013

(54) HIGH-PERFORMANCE HETEROSTRUCTURE FET DEVICES AND METHODS

(71) Applicants: Yungryel Ryu, Columbia, MO (US); Tae-Seok Lee, Columbia, MO (US); Jorge Lubguban, Columbia, MO (US); Henry W. White, Columbia, MO (US)

(72) Inventors: Yungryel Ryu, Columbia, MO (US); Tae-Seok Lee, Columbia, MO (US); Jorge Lubguban, Columbia, MO (US); Henry W. White, Columbia, MO (US)

(73) Assignee: MOXTRONICS, INC., Columbia, MO (US)

(21) Appl. No.: 12/740,671

(22) PCT Filed: Oct. 29, 2008
(86) PCT No.: PCT/US2008/081556

§ 371 Date: Oct. 6, 2010

Related U.S. Application Data
(60) Provisional application No. 60/983,652, filed on Oct. 30, 2007.

(51) Int. Cl. H01L 29/78

(52) U.S. Cl. CPC H01L 29/78
USPC 257/43

(57) ABSTRACT

A layered heterostructure field effect transistor (HFET) comprises a substrate, a first semiconductor oxide layer grown on the substrate, and a second semiconductor oxide layer grown on the first layer semiconductor layer and having an energy band gap different from that of the first semiconductor layer, and the second layer also having a gate region and a drain region and a source region with electrical contacts to gate, drain and source regions sufficient to form a HFET. The substrate may be a material, including a single crystal material, and may contain a buffer layer material on which the first semiconductor layer is grown. The conductivity type of the first and second semiconductor layers and the composition of the semiconductor oxide layers can be selected to improve performance for desired operational features of the HFET. This layered structure can be applied for the improvement in the function and high frequency and high power performance of semiconductor HFET devices.

### CROSS-REFERENCE TO RELATED APPLICATION, PRIORITY BENEFIT

This application for patent claims the priority benefit of U.S. Provisional Application for Patent Ser. No. 60/983652 filed Oct. 30, 2007, entitled High-Performance Heterostructure FET Devices and Methods, incorporated by reference herein as if set forth herein in its entirety.

### FIELD OF THE INVENTION

The present invention relates generally to semiconductor oxide heterostructure field effect transistor (HFET) devices, and more particularly, to improvements in the high frequency and high power performance of HFET devices, as well as methods related to such devices.

### BACKGROUND OF THE INVENTION

A field effect transistor (FET) device can be used in an amplifier circuit to increase radio frequency (RF) power. A conventional FET has a simple structure and can be fabricated easily. Gallium arsenide has been used to obtain high frequency performance. Wide bandgap semiconductor materials, such as silicon carbide and gallium nitride, can also be used to obtain high power performance, particularly In adverse operating conditions such as high temperature and high radiation conditions.

Electrical charges flow between drain and source regions through the active semiconductor layer of a FET, with the gate region located between the drain and source. Electrical carriers of either n-type or p-type conductivity exist in the active layer, and will move in response to an electric field generated between the source region and the drain region formed thereon, and in response to signal voltage applied to the gate voltage. The metal gate contact may form electrical contact to the active layer region by several different means, leading to several different FET types. The active channel is that portion within the active layer in which the electrical carriers move in response to a signal on the gate contact. The speed of a FET pertains to its ability to operate at high frequency, and high carrier mobility is required for high speed response. Enhancements in the ability of a FET to operate at high frequencies and to increase its functionally and the number of potential applications for which it can be employed. Various designs for epitaxially layered structures have been disclosed or are known in the prior art to increase performance of FETs at high frequencies, and to extend the maximum frequency at which a FET will operate.

As noted above, there exist various types of FETs. For example, a FET may have no intermediate layer between a metal gate contact and the active layer, in which case a metal semiconductor field effect transistor (MESFET) is formed. Alternatively, a FET may further include an additional material layer between the gate contact and the active layer, to form a junction field effect transistor (JFET), or may include a metal oxide material layer between the gate contact and the active layer to form a metal oxide field effect transistor (MOSFET).

The upper limit for the operating frequency for a FET can be improved by several methods. It is desirable to have high electron mobility for a FET that has n-type carriers in the active channel. For high frequency applications, the preferred active layer materials have been those having a high saturated electron drift velocity. Because a FET is a layered device, the structure and electrical properties of certain layers within the structure can critically affect the overall characteristics of the device.

Various types of FETs are discussed or disclosed in the following U.S. patents, which are incorporated herein by reference as if set forth herein in their entireties:

| | |
|---|---|
| 6,806,157 | Yang et al. |
| 6,559,068 | Alok et al. |
| 6,274,916 | Donath et al. |
| 5,821,576 | Sriran |
| 3,729,045 | Buynoski |
| 5,643,811 | Hasegawa |
| 5,399,883 | Baliga |
| 5,298,441 | Goronkin et al. |
| 5,270,554 | Palmour |
| 5,227,644 | Ueno |
| 5,081,511 | Tehrani et al |
| 4,935,377 | Strifler et al. |

By way of further background with regard to the present invention, wide bandgap semiconductor materials are useful for device operation at high temperatures. Zinc oxide is a wide bandgap material, and it also possesses good radiation resistance properties. Wide bandgap semiconductor films of zinc oxide are now available in both n-type and p-type carrier types that have properties sufficient for fabrication of, semiconductor devices. In addition, wide bandgap semiconductor alloy materials are useful for device operation at high temperatures. Beryllium zinc oxide is a wide bandgap material, and it also possesses good radiation resistance properties. Wide bandgap semiconductor films of beryllium zinc oxide are now available in both n-type and p-type carrier types that have properties sufficient for fabrication of semiconductor devices.

In addition, U.S. Pat. No. 6,291,085 to White et al. disclosed a p-type doped zinc oxide film, wherein the film could be incorporated into a semiconductor device including an FET.

U.S. Pat. No. 6,342,313 to White et al. disclosed a p-type doped metal oxide film having a net acceptor concentration of at least about 10¹⁵ acceptors/cm³, wherein:

(1) the film is an oxide compound of an element selected from the groups consisting of Group 2 (beryllium, magnesium, calcium, strontium, barium and radium), Group 12 (zinc, cadmium and mercury), Group 2 and 12, and Group 12 and Group 16 (oxygen, sulfur, selenium, tellurium and polonium) elements, and

(2) wherein the p-type dopant is an element selected from the groups consisting of Group 1 (hydrogen, lithium, sodium, potassium, rubidium, cesium and francium), Group 11 (copper, silver and gold). Group 5 (vanadium, niobium and tantalum) and Group 15 (nitrogen, phosphorous, arsenic, antimony and bismuth) elements.

U.S. Pat. No. 6,410,162 to White et al. disclosed a p-type doped zinc oxide film, wherein the p-type dopant is selected from Group 1, 11, 5 and 15 elements, and wherein the film is incorporated into a semiconductor device including a FET. This patent also disclosed a p-type doped zinc oxide film, wherein the p-type dopant is selected from Group 1, 11, 5 and 15 elements, and wherein the film is incorporated into a semiconductor device as a substrate material for lattice matching to materials in the device.

PCT Application Serial No. PCT/US06/02534 to Ryu et al. disclosed (beryllium, zinc, and oxygen) alloys with energy band gaps that are higher than the energy band gap of zinc oxide and (zinc, cadmium, selenium, sulfur and oxygen) alloys with energy band gap that are lower than the energy band gap of zinc oxide. They also disclosed p-type doped (beryllium, zinc, and oxygen) alloys; namely, BeZnO alloys, and (zinc, cadmium, selenium, and oxygen) alloys; namely, ZnCdScO alloys, having net acceptor concentration of at least about 10¹⁵ acceptors/cm³, wherein:

(1) the p-type dopant is an element selected from the groups consisting of Group 1 (hydrogen, lithium, sodium, potassium, rubidium, cesium and francium), Group 11 (copper, silver and gold), Group 5 (vanadium, niobium and tantalum) and Group 15 (nitrogen, phosphorous, arsenic, antimony and bismuth) elements,

(2) the p-type dopant comprises arsenic; and

(3) alloy layers are incorporated into a semiconductor device including a FET.

Each of the above-referenced documents is incorporated by reference herein, and made a part of this application for patent, as if set forth in its entirety herein.

Those skilled in the art will appreciate that an HFET comprising a heterostructure layer can improve the performance of the device at high frequency and at high power. HFET devices that can operate at high speed and high power are desirable for use in many commercial and military sectors, including, but not limited to, areas such as communication networks, radar, sensors and medical imaging.

There exists a need for an HFET which may be fabricated of wide bandgap semiconductor materials such as zinc oxide and beryllium zinc oxide alloy material, and with the HFET having a heterostructure such that the HFET has improved performance in function and speed and can be used at high power.

### SUMMARY OF THE INVENTION

The present invention addresses these needs, among other aspects. In various embodiments and practices, the invention provides layered heterostructures (and methods related to such layered heterostructures) for improvement in function and speed for HFET devices, and with particular capabilities for operation at high frequencies and at high powers.

One embodiment of the invention provides a heterostructure field effect transistor (HFET) comprising a single crystal silicon carbide substrate, a first semiconductor layer of zinc oxide grown on the single crystal silicon carbide substrate, a second semiconductor layer of n-type zinc oxide grown on the first semiconductor layer, and a third semiconductor layer of n-type beryllium zinc oxide alloy grown on the second semiconductor layer. The first semiconductor layer serves as a buffer layer. The second semiconductor layer serves as the active layer. The energy band gap of the third semiconductor layer is larger than that of the second semiconductor layer. A source region contact area and a drain region contact area are located on the third layer. Electrical leads are applied to the source and drain contact areas to form ohmic contacts. A metal gate contact is formed on the third semiconductor layer located between the source and drain regions, thereby forming a Schottky barrier contact to the third semiconductor layer. An electrical lead is applied to the metal gate contact. The device formed is an HFET.

Thus, with regard to the present invention, a layered heterostructure FET (HFET) in accordance with the invention employs semiconductor layers having different energy band gaps. As one example of a HFET, a semiconductor layer with an energy band gap higher than that of the active layer can be grown on the active layer. The source and drain can be formed on the topmost semiconductor layer. With regard to the present invention, a p-type zinc oxide layer may be deposited on a p-type beryllium zinc oxide layer prior to metallization to increase ohmic contact; an n-type zinc oxide layer may be deposited on a p-type beryllium zinc oxide layer prior to metallization to increase ohmic contact; a metal gate contact can be formed on the topmost semiconductor layer, thereby forming a Schottky barrier contact with the topmost semiconductor layer, and thereby forming a MESFET. Alternatively, a material can be deposited on the topmost semiconductor layer prior to forming the gate contact to form MOSFET and JFET devices.

Without limiting the scope of the present invention, other embodiments, examples or aspects of the invention may employ or provide one or more of the following:

1) A single crystal substrate selected from the group comprising, but not limited to, silicon carbide, zinc oxide, gallium nitride, gallium arsenide, sapphire, silicon, glasses, plastics and polymers.

2) A single crystal substrate that is doped.

3)A beryllium zinc oxide layer that helps confine electrical carriers to the zinc oxide layer of the HFET.

4) (Beryllium, magnesium, zinc, and oxygen) alloys (BeMgZnO alloys) employed as a semiconductor layer.

5) (Group 11 elements, zinc, and oxygen) alloys employed as a semiconductor layer.

6) BeMgZnO alloys employed as a semiconductor layer wherein magnesium can be used to improve lattice matching between adjacent layers and between a layer and a substrate or buffer layer.

7) (Zinc, cadmium, selenium, sulfur, and oxygen) alloys (ZnCdSeSO alloys) employed as a semiconductor layer.

8) (Zinc, cadmium, selenium, sulfur, beryllium, and oxygen) alloys (BeZnCdSeSO alloys) employed as a semiconductor layer wherein beryllium can be used to improve lattice matching between adjacent layers and between a layer and a substrate or butler layer.

9) Portions of the topmost semiconductor layer in a HFET may be removed to expose an underlying semiconductor layer so that the drain and source make electrical contact to the underlying semiconductor layer.

10) Layers may be grown epitaxially to improve device performance.

These and other embodiments, examples, practices and aspects of the present invention are described in detail below and in conjunction with the attached drawing figures. In particular, other details, advantages and features of the invention, and the manner in which operation of HFET devices in accordance with the invention can be carried out, will become more apparent to one skilled in the art front the following detailed description of the invention, in conjunction with the accompanying drawings that illustrate exemplary embodiments of the invention.

### BRIEF DESCRIPTION OF THE DRAWINGS

FIG. 1 is a schematic diagram illustrating one embodiment of an HFET in accordance with the present invention.

FIG. 2A is a top view of an exemplary HFET like that shown in FIG. 1, in accordance with the present invention.

FIG. 2B is an elevation view of an exemplary HFET like that shown in FIG. 1.

FIG. 3 is a plot of drain current as a function of voltage applied between the drain and source of an exemplary HFET like that shown in FIG. 1.

FIG. 4 is a plot of drain current vs. gate bias voltage measured with respect to the source at a selected value for the drain voltage, of an exemplary HFET like that shown in FIG. 1.

FIGS. 5-25 are schematic diagrams illustrating other embodiments of HFETS in accordance with the present invention.

### DETAILED DESCRIPTION OF THE INVENTION

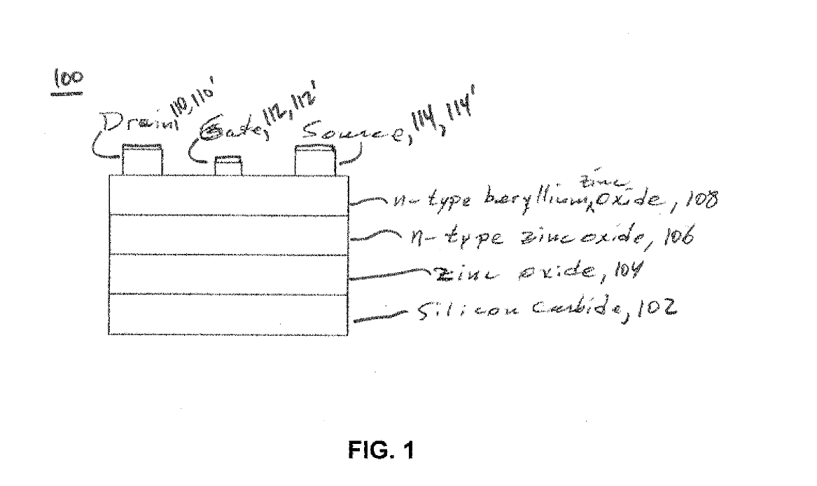

FIG. 1 is a schematic diagram of one embodiment of an HFET 100 in accordance with the present invention. In particular, FIG. 1 is cross-section view that illustrates the layered structure of an HFET in accordance with the invention.

As indicated in FIG. 1, a first semiconductor layer of zinc oxide 104 is grown on a single crystal silicon carbide substrate 102. A second semiconductor layer of n-type zinc oxide 106 is grown on the first semiconductor layer 104, and a third semiconductor layer of n-type beryllium zinc oxide alloy 108 is grown on the second semiconductor layer 106. The:first semiconductor layer serves as a buffer layer. The second semiconductor layer serves as the active layer. The energy band gap of the third semiconductor layer is larger than that of the second semiconductor layer. A source region contact area 114 and a drain region contact area 110 are located on the third layer. Electrical leads 114′ and 110′ are applied to the source and drain contact areas to form ohmic contacts. A metal gate contact 112 is formed on the third semiconductor layer located between the source and drain regions, thereby forming a Schottky barrier contact to the third semiconductor layer. An electrical lead 112′ is applied to the metal gate contact 112. The device formed is an HFET.

Techniques of growing layers, applying electrical leads, and forming metal gate contacts, for example, may include techniques known in the art, or techniques described in patent applications of one or more of the inventors named in the present application for patent (which other applications are incorporated by reference herein)

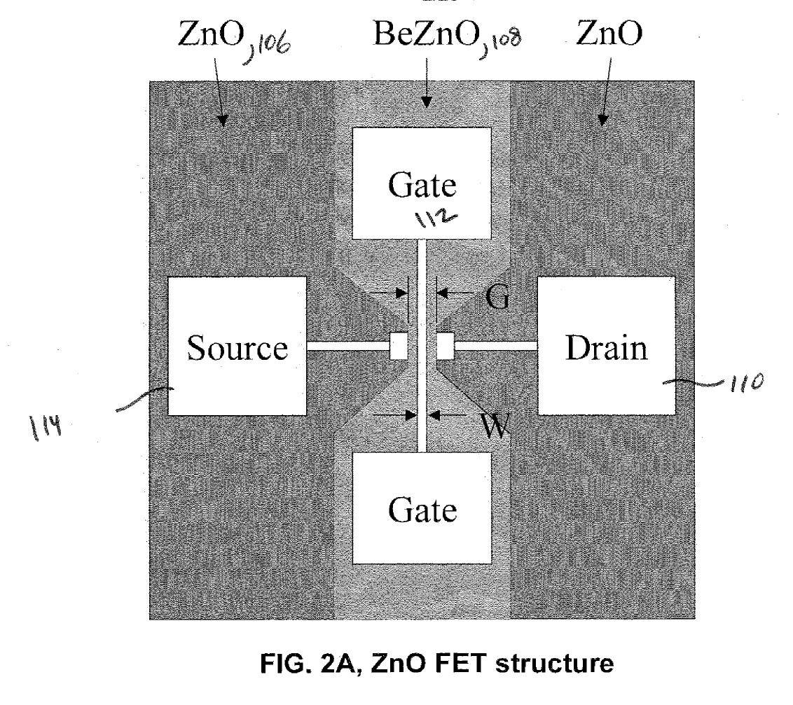

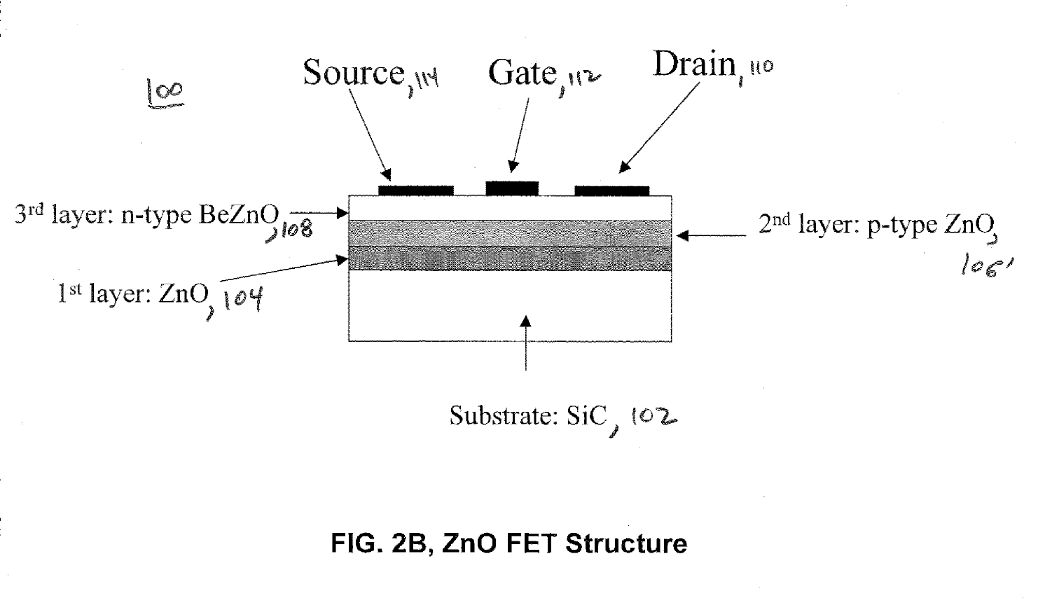

FIG. 2A is a schematic top view of the exemplary HFET 100 of FIG. 1 in accordance with the present invention, illustrating the layout of the source 114, drain 110 and gate 112 electrodes. The separation between the source and drain contact areas is the gate length and is denoted as G. The length of the gate electrode is denoted as W, and is measured along the line through source and drain. For the first embodiment, G=40 μm (40 microns), and W=30 μm (30 microns).

FIG. 2B is a schematic elevation view of the exemplary HFET 100 of FIG. 1 in accordance with the present invention, illustrating the semiconductor layers comprising the device (in this example, using a p-type ZnO second layer 106′) and the location of the source 114, gate 112, and drain 110.

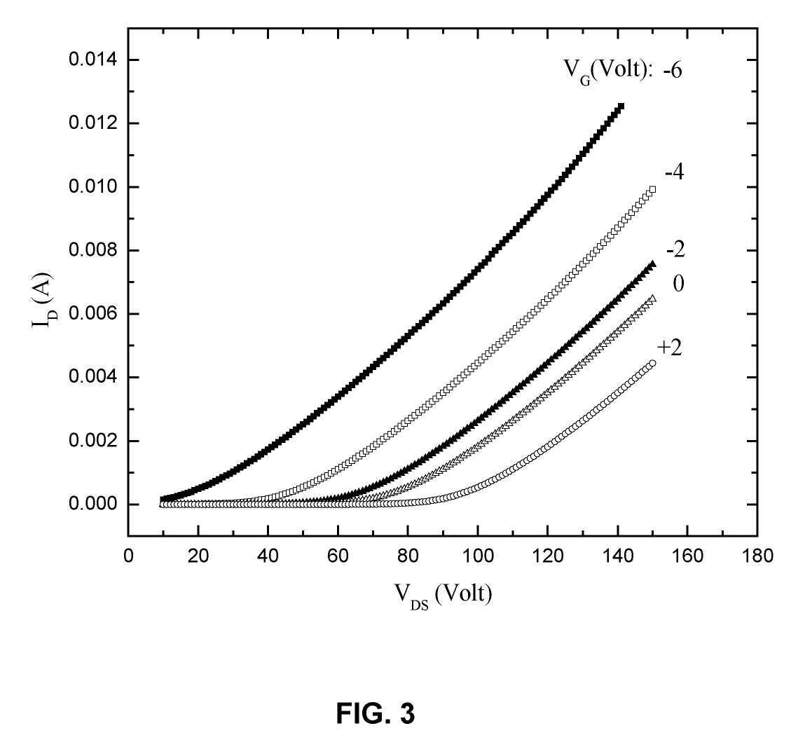

FIG. 3 is a plot of the drain current, I_{D}, in units of amperes (A), as a function of voltage applied between the drain and source, V_{DS}, in units of volts, at selected values for the voltage applied to the gate, V_{G}, that range from +2 volts to −6 volts measured with respect to the source, for the first embodiment of a heterostructure field effect transistor (HFET) in accordance with the present invention. The gate length is 30 microns. The active layer is p-type zinc oxide doped with arsenic.

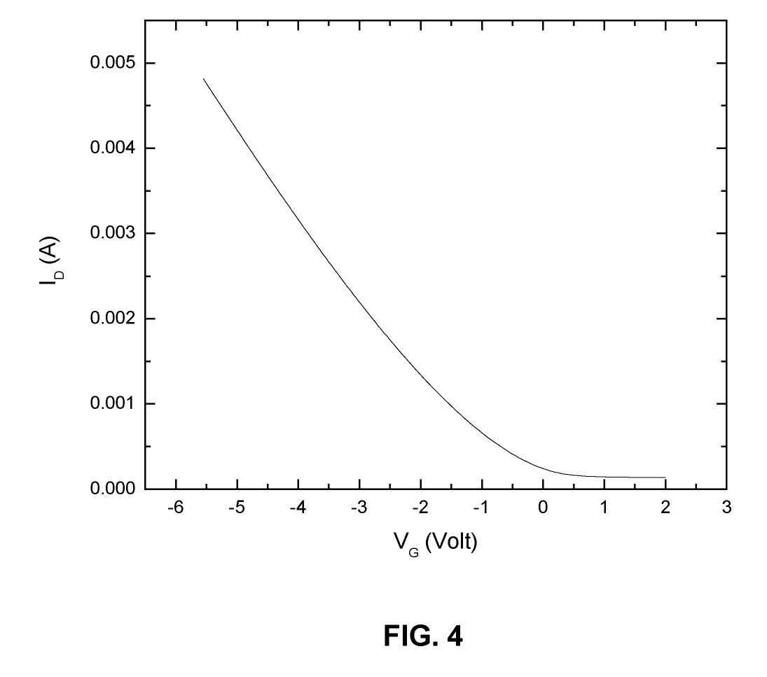

FIG. 4 shows drain current, I_{D}, versus gate bias voltage, V_{G}, measured with respect to the source at a selected value for the drain voltage, V_{D}, equal to +5 volts measured with respect to the source for the first embodiment of a heterostructure field effect transistor (HFET) in accordance with the present invention. The active layer is n-type zinc oxide doped with gallium.

Examples using a ZnO First Layer and n-type BeZnO Second Layer (Higher Band Gap):

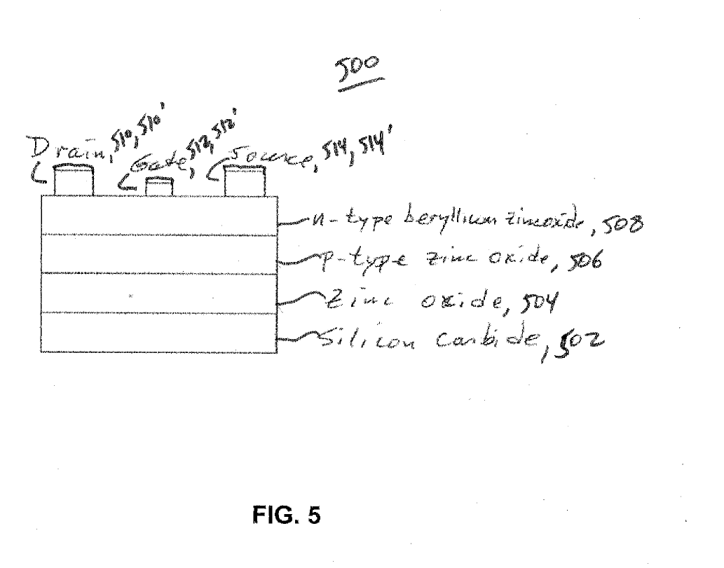

FIG. 5 depicts another HFET embodiment 500 of the invention. A first semiconductor layer of zinc oxide 504 is grown on a single crystal silicon carbide substrate 502. A second semiconductor layer of p-type zinc oxide 506 is grown on the first semiconductor layer, and a third semiconductor layer of n-type beryllium zinc oxide alloy 508 is grown on the second semiconductor layer. The first semiconductor layer serves as a buffer layer. The second semiconductor layer serves as the active layer. The energy band gap of the third semiconductor layer is larger than that of the second semiconductor layer. A source region contact area 514 and a drain region contact area 510 are located on the third layer. Electrical leads 514′, 510′ are applied to the source and drain contact areas, respectively, to form ohmic contacts. A metal gate contact 512 is formed on the third semiconductor layer located between the source and drain regions, thereby forming a Schottky barrier contact to the third semiconductor layer. An electrical lead 512′ is applied to the metal gate contact. The device thus formed is an HFET 500 in accordance with the invention.

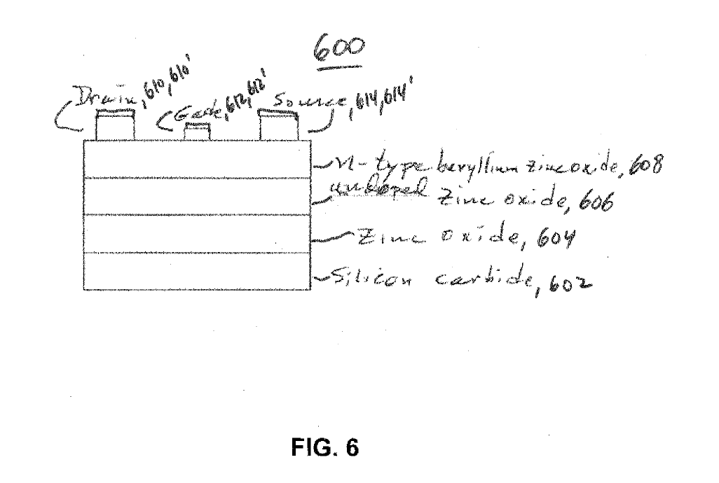

FIG. 6 illustrates another HFET embodiment 600 of the invention. A first semiconductor layer of zinc oxide 604 is grown on a single crystal silicon carbide substrate 602. A second semiconductor layer of undoped zinc oxide 606 is grown on the first semiconductor layer, and a third semiconductor layer of n-type beryllium zinc oxide alloy 608 is grown on the second semiconductor layer. The first semiconductor layer serves as a buffer layer. The second semiconductor layer serves as the active layer. The energy band gap of the third semiconductor layer is larger than that of the second semiconductor layer. A source region contact area 614 and a drain region contact area 610 are located on the third layer. Electrical leads 614′, 610′ are applied to the source and drain contact areas to form ohmic contacts. A metal gate contact 612 is formed on the third semiconductor layer located between the source and drain regions, thereby forming a Schottky barrier contact to the third semiconductor layer. An electrical lead 612′ is applied to the metal gate contact 612. The device thus formed is an HFET 600 in accordance with the invention.

### Example Like the Foregoing, but Without a Buffer Layer:

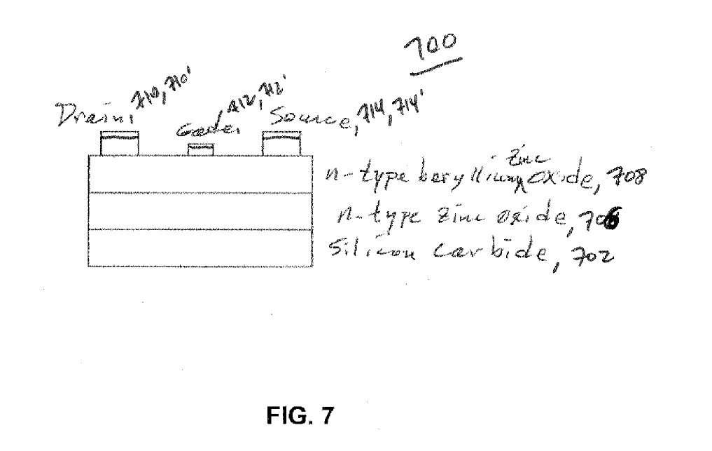

FIG. 7 depicts another HFET embodiment of the invention. A first semiconductor layer of n-type zinc oxide 706 is grown on a single crystal silicon carbide substrate, and a second semiconductor layer of n-type beryllium zinc oxide alloy 708 is grown on the first semiconductor layer. The first semiconductor layer serves as the active layer. The energy band gap of the second semiconductor layer is larger than that of the first semiconductor layer. A source region contact area 714 and a drain region contact area 710 are located on the second layer. Electrical leads 714′, 710′ are applied to the source and drain contact areas to form ohmic contacts. A metal gate contact 712 is formed on the second semiconductor layer located between the source and drain regions, thereby forming a Schottky barrier contact to the second semiconductor layer. An electrical lead 712′ is applied to the metal gate contact 712. The device formed is an HFET 700 according to the invention.

Examples using ZnO First Layer and p-Type BeZnO Second Layer with Buffer Layer

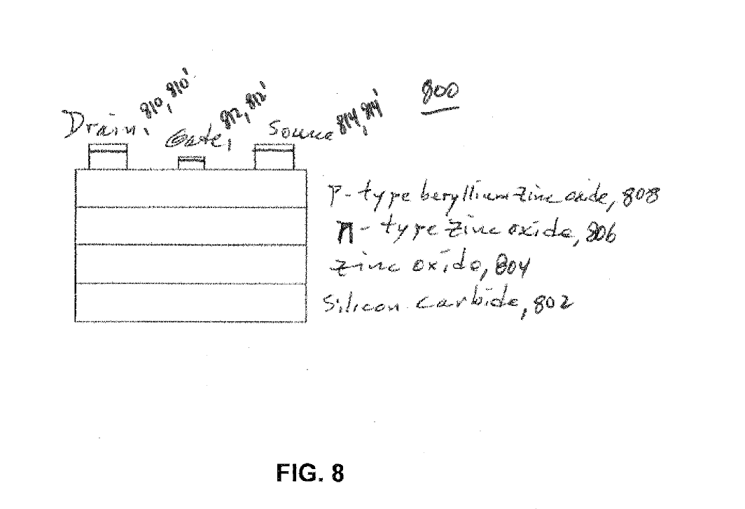

FIG. 8 illustrates another HFET embodiment 800 of the invention. A first semiconductor layer of zinc oxide 804 is grown on a single crystal silicon carbide substrate 802. A second semiconductor layer 806 of n-type zinc oxide is grown on the first semiconductor layer, and a third semiconductor layer of p-type beryllium zinc oxide alloy 808 is grown on the second semiconductor layer. The first semiconductor layer serves as a buffer layer. The second semiconductor layer serves as the active layer. The energy band gap of the third semiconductor layer is larger than that of the second semiconductor layer. A source region contact area 814 and a drain region contact area 810 are located on the third layer. Electrical leads 814′, 810′ are applied to the source and drain contact areas to form ohmic contacts. A metal gate contact 812 is formed on the third semiconductor layer located between the source and drain regions, thereby forming a Schottky barrier contact to the third semiconductor layer. An electrical lead 812′ is applied to the metal gate contact. The device formed is an HFET 800 according to the invention.

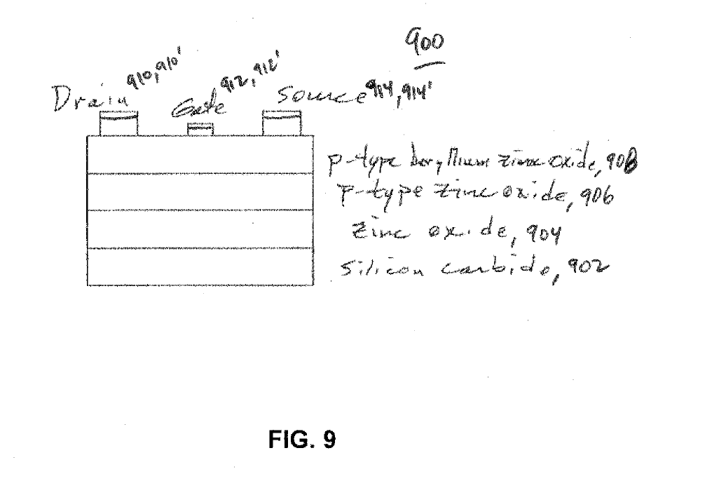

FIG. 9 illustrates another HFET embodiment 900 of the invention. A first semiconductor layer 904 of zinc oxide is grown on a single crystal silicon carbide substrate 902. A second semiconductor layer 906 of p-type zinc oxide is grown on the first semiconductor layer, and a third semiconductor layer 908 of p-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. A source region contact area 914 and a drain region contact area 910 are located on the third layer. Electrical leads 914′, 910′ are applied to the source and drain contact areas, respectively, to form ohmic contacts. A metal gate contact 912 is formed on the third semiconductor layer located between the source and drain regions, thereby forming a Schottky barrier contact to the third semiconductor layer. An electrical lead 912′ is applied to the metal gate contact. The device formed is an HFET 900 according to the invention.

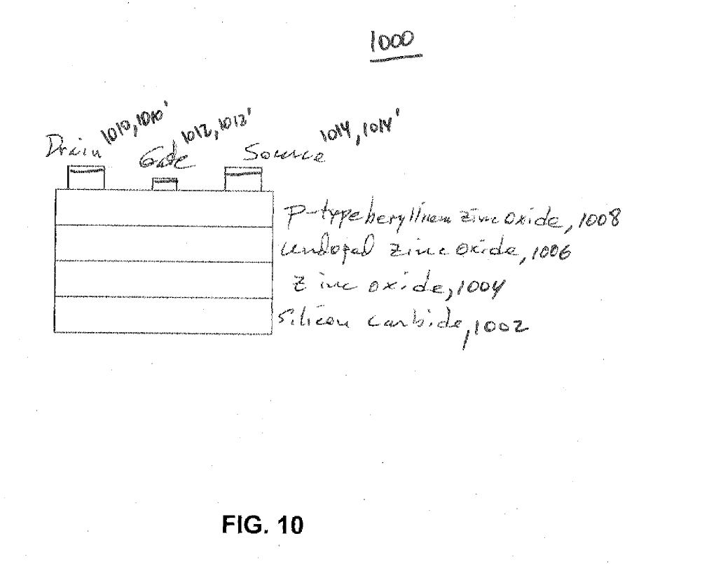

FIG. 10 illustrates another HFET embodiment 1000 of the invention. A first semiconductor layer of zinc oxide 1004 is grown on a single crystal silicon carbide substrate 1002. A second semiconductor layer 1006 of undoped zinc oxide is grown on the first semiconductor layer, and a third semiconductor layer 1008 of p-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. A source region contact area 1014 and a drain region contact area 1010 are located on the third layer. Electrical leads 1014′, 1010′, respectively, are applied to the source and drain contact areas to form ohmic contacts. A metal gate contact 1012 is formed on the third semiconductor layer located between the source and drain regions, thereby forming a Schottky barrier contact to the third semiconductor layer. An electrical lead 1012′ is applied to the metal gate contact. The device fanned is an HFET 1000 according to the invention.

### Example Without a Buffer Layer

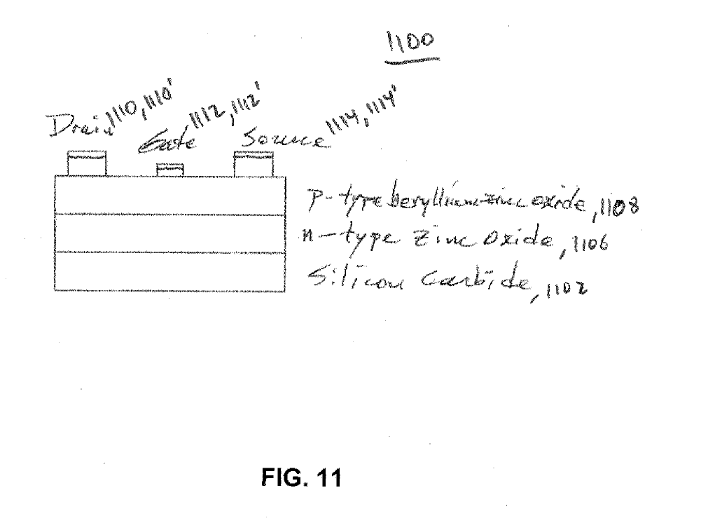

FIG. 11 illustrates another HFET embodiment 1100 of the invention. A first semiconductor layer of n-type zinc oxide 1106 is grown on a single crystal silicon carbide substrate 1102, and a second semiconductor layer of p-type beryllium zinc oxide alloy 1108 is grown on the first semiconductor layer. The first semiconductor layer serves as the active layer. The energy band gap of the second semiconductor layer is larger than that of the first semiconductor layer. A source region contact area 1114 and a drain region contact area 1110 are located on the second layer. Electrical leads 1114′, 1110′, respectively, are applied to the source and drain contact areas to form ohmic contacts. A metal gate contact 1112 is formed on the second semiconductor layer located between the source and drain regions, thereby forming a Schottky barrier contact to the second semiconductor layer. An electrical lead 1112′ is applied to the metal gate contact. The device formed is an HFET 1100 according to the invention.

Examples using BeZnO (Higher Band Gap) First Layer with n-Type ZnO on Top and ZnO Buffer Layer

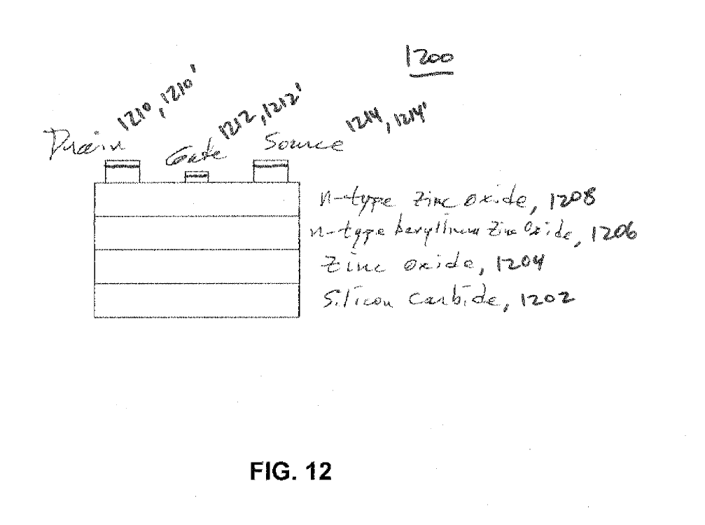

FIG. 12 illustrates still another HFET embodiment 1200 of the invention. A first semiconductor layer 1204 of zinc oxide is grown on a single crystal silicon carbide substrate 1202. A second semiconductor layer 1206 of n-type beryllium zinc oxide alloy is grown on the first semiconductor layer, and a third semiconductor layer 1208 of n-type zinc oxide is grown on the second semiconductor layer. The first semiconductor layer serves as a buffer layer. The energy band gap of the second semiconductor layer is larger than that of the third semiconductor layer. The third semiconductor layer serves as the active layer. A source region contact area 1214 and a drain region contact area 1210 are located on the third layer. A metal gate contact 1212 is formed on the third semiconductor layer at a location between the source and drain regions, thereby forming a Schottky barrier contact to the third semiconductor layer. Electrical leads 1214′, 1210′, respectively, are applied to the source and drain contact areas to form ohmic contacts. An electrical lead 1212′ is applied to the metal gate contact. The device formed is an HFET 1200 according to the invention.

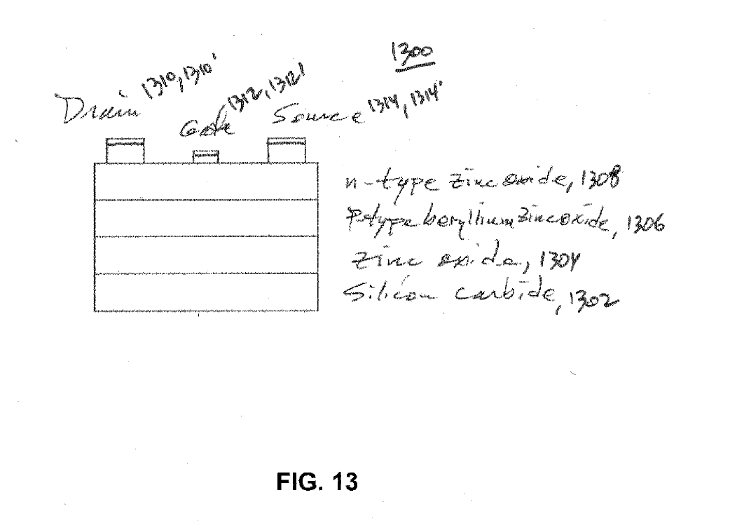

FIG. 13 illustrates vet another HFET embodiment 1300 of the invention. A first semiconductor layer 1304 of zinc oxide is grown on a single crystal silicon carbide substrate 1302. A second semiconductor layer 1306 of p-type beryllium zinc oxide alloy is grown on the first semiconductor layer, and a third semiconductor layer 1308 of n-type zinc oxide is grown on the second semiconductor layer. The first semiconductor layer serves as a buffer layer. The energy band gap of the second semiconductor layer is larger than that of the third semiconductor layer. The third semiconductor layer serves as the active layer. A source region contact area 1314 and a drain region contact area 1310 are located on the third layer. A metal gate contact 1312 is formed on the third semiconductor layer at a location between the source and drain regions, thereby forming a Schottky barrier contact to the third semiconductor layer. Electrical leads 1314′, 1310′, respectively, are applied to the source and drain contact areas to form ohmic contacts. An electrical lead 1312′ is applied to the metal gate contact. The device formed is an HFET 1300 according to the invention.

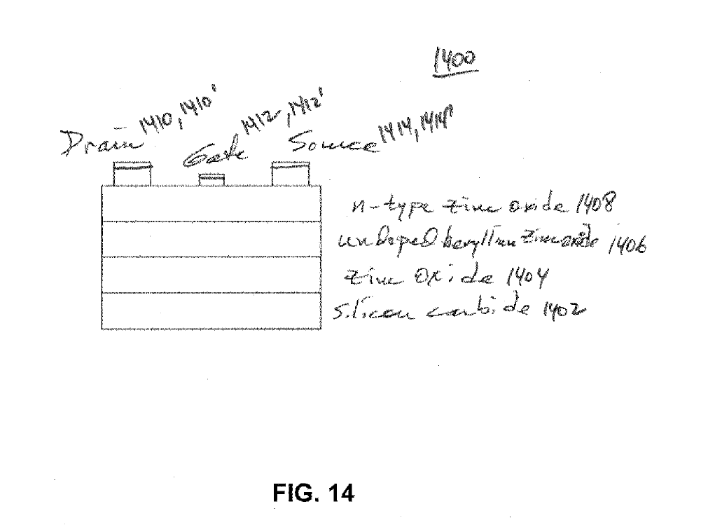

FIG. 14 illustrates another HFET embodiment 1400 of the invention. A first semiconductor layer 1404 of zinc oxide is grown on a single crystal silicon carbide substrate 1402. A second semiconductor layer 1406 of undoped beryllium zinc oxide alloy is grown on the first semiconductor layer, and a third semiconductor layer 1408 of n-type zinc oxide is grown on the second semiconductor layer. The first semiconductor layer serves as a buffer layer. The energy band gap of the second semiconductor layer is larger than that of the third semiconductor layer. The third semiconductor layer serves as the active layer. A source region contact area 1414 and a drain region contact area 1410 are located on the third layer. A metal gate contact 1412 is formed on the third semiconductor layer at a location between the source and drain regions, thereby forming a Schottky barrier contact to the third semiconductor layer. Electrical leads 1414′, 1410′ are applied to the source and drain contact areas to form ohmic contacts. An electrical lead 1412′ is applied to the metal gate contact. The device formed is an HFET 1400 according to the invention.

Example without Buffer Layer

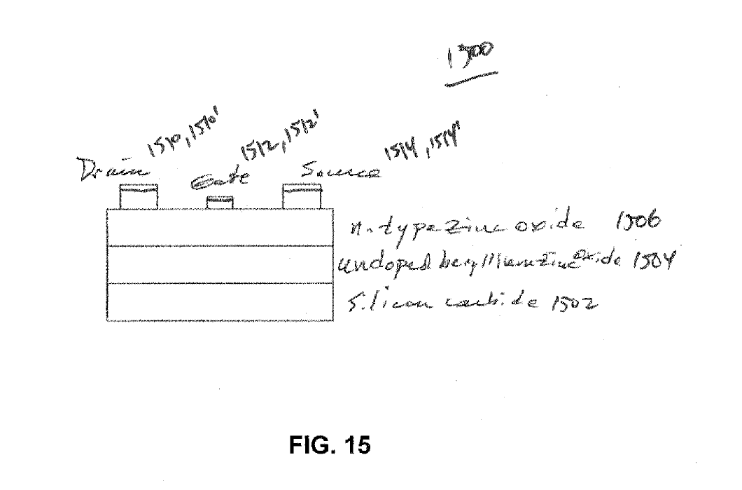

FIG. 15 illustrates another HFET embodiment 1500 of the invention. A first semiconductor layer 1504 of undoped beryllium zinc oxide alloy is grown on a single crystal silicon carbide substrate 1502, and a second semiconductor layer 1506 of n-type zinc oxide is grown on the first semiconductor layer. The energy band gap of the first semiconductor layer is larger than that of the second semiconductor layer. The second semiconductor layer serves as the active layer. A source region contact area 1514 and a drain region contact area 1510 are located on the second layer. A metal gate contact 1512 is formed on the second semiconductor layer at a location between the source and drain regions, thereby forming a Schottky barrier contact to the second semiconductor layer. Electrical leads 1514′, 1510′ are applied to the source and drain contact areas to form ohmic contacts. An electrical lead 1512′ is applied to the metal gate contact. The device formed is an HFET 1500 according to the invention.

Examples in Which Drain and Source Contact “punch” Through Topmost BeZnO Layer and Electronically Contact ZnO Layer

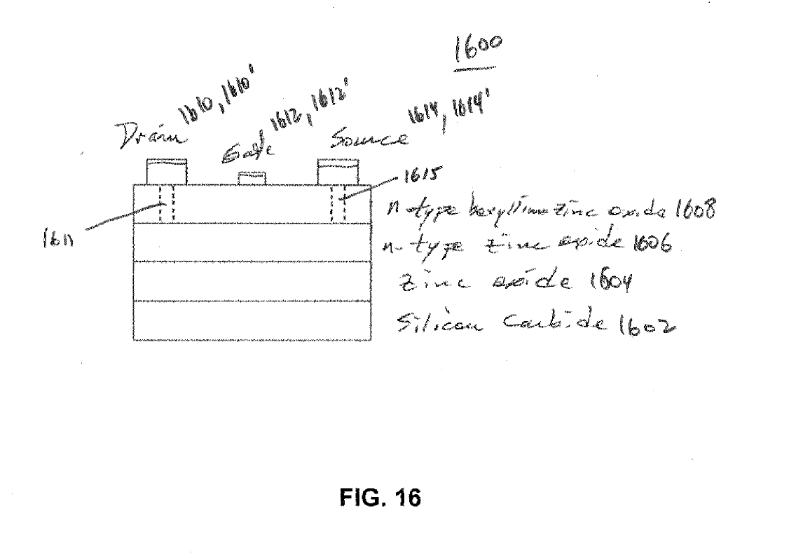

FIG. 16 is a schematic diagram of an HFET 1600 in accordance with the invention, showing a cross section having a layered structure like that of FIG. 1, but with certain differences. As illustrated in FIG. 16, a first semiconductor layer 1604 of zinc oxide is grown on a single crystal silicon carbide substrate 1602. A second semiconductor layer 1606 of n-type zinc oxide is grown on the first semiconductor layer, and a third semiconductor layer 1608 of n-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. Portions 1615, 1611 of the third layer are removed to expose access sites on the second semiconductor layer to form a source region contact area 1614 and a drain region contact area 1610 that are located on the second semiconductor layer. Electrical leads 1614′, 1610′ are applied to the source and drain contact areas to form ohmic contacts to the second semiconductor layer. A metal gate contact 1612 is formed on the third semiconductor layer located between the source and drain regions, thereby forming a Schottky barrier contact to the third semiconductor layer. An electrical lead 1612′ is applied to the metal gate contact. The device formed is an HFET 1600 according to the invention.

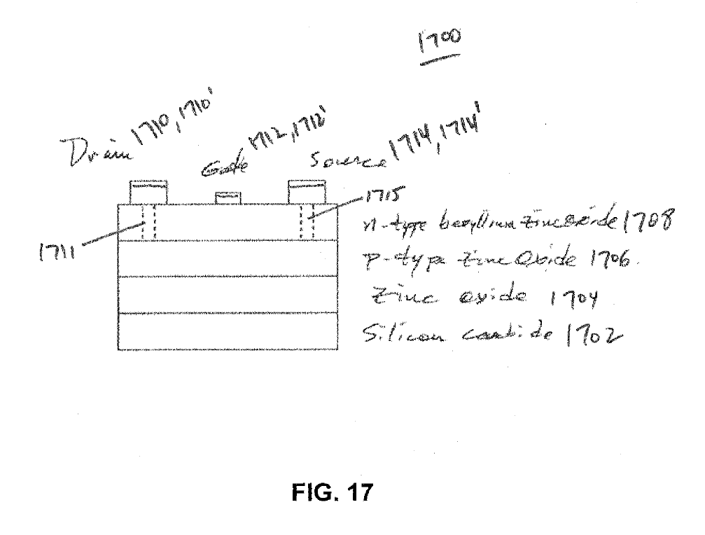

FIG. 17 illustrates another HFET embodiment 1700 of the invention. A first semiconductor layer 1704 of zinc oxide is grown on a single crystal silicon carbide substrate 1702. A second semiconductor layer 1706 of n-type zinc oxide is grown on the first semiconductor layer, and a third semiconductor layer 1708 of n-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. Portions 1715, 1711 of the third layer are removed to expose access sites on the second semiconductor layer to form a source region contact area 1714 and a drain region contact area 1710 that are located on the second semiconductor layer. Electrical leads 1714′, 1710′ are applied to the source and drain contact areas to form ohmic contacts to the second semiconductor layer. A metal gate contact 1712 is formed on the third semiconductor layer located between the source and drain regions, thereby forming a Schottky barrier contact to the third semiconductor layer. An electrical lead 1712′ is applied to the metal gate contact. The device formed is an HFET 1700 according to the invention.

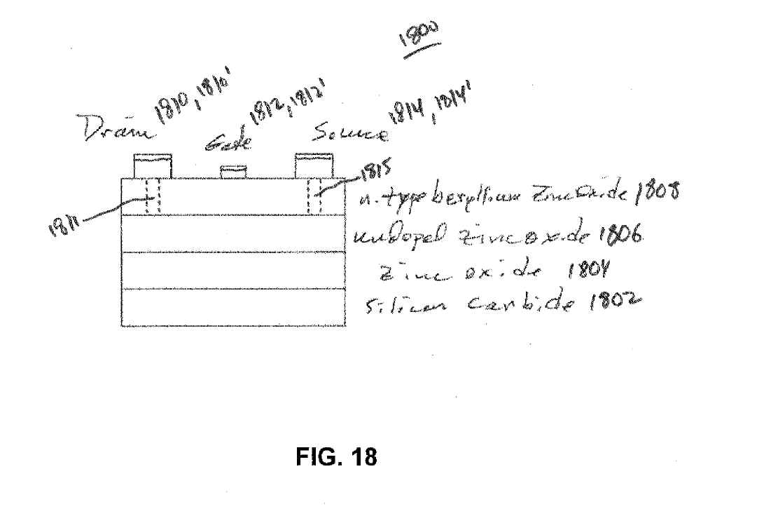

FIG. 18 illustrates another HFET embodiment 1800 of the invention. A first semiconductor layer 1804 of zinc oxide is grown on a single crystal silicon carbide substrate 1802. A second semiconductor layer 1806 of undoped zinc oxide is grown on the first semiconductor layer, and a third semiconductor layer 1808 of n-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. Portions 1815, 1811 of the third layer are removed to expose access sites on the second semiconductor layer to form a source region contact area 1814 and a drain region contact area 1810 that are located on the second semiconductor layer. Electrical leads 1814′, 1810′ are applied to the source and drain contact areas to form ohmic contacts to the second semiconductor layer. A metal gate contact 1812 is formed on the third semiconductor layer located between the source and drain regions, thereby forming a Schottky barrier contact to the third semiconductor layer. An electrical lead 1812′ is applied to the metal gate contact. The device formed is an HFET 1800 according to the invention.

Example without Buffer

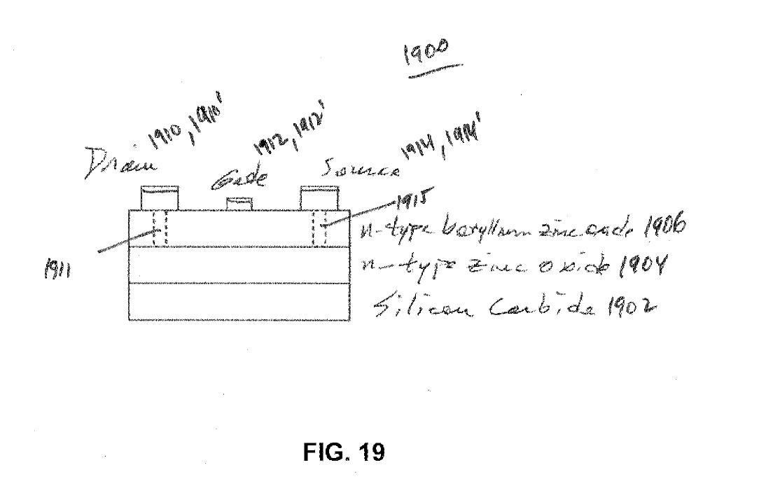

FIG. 19 illustrates another HFET embodiment 1900 of the invention. A first semiconductor layer 1904 of n-type zinc oxide is grown on a single crystal silicon carbide substrate 1902, and a second semiconductor layer 1906 of n-type beryllium zinc oxide alloy is grown on the first semiconductor layer. The first semiconductor layer serves as the active layer. The energy band gap of the second semiconductor layer is larger than that of the first semiconductor layer. Portions 1915, 1911 of layer 1906 are removed to expose access sites on layer 1904 to form a source region contact area 1914 and a drain region contact area 1910. A source region contact area 1914 and a drain region contact area 1910 are located on the second layer. Electrical leads 1914′, 1910′ are applied to the source and drain contact areas to form ohmic contacts. A metal gate contact 1912 is formed on the second semiconductor layer located between the source and drain regions, thereby forming a Schottky barrier contact to the second semiconductor layer. An electrical lead 1912′ is applied to the metal gate contact. The device formed is an HFET 1900 according to the invention.

Examples with First Layer ZnO, Second Layer p-Type BeZnO (Higher Band Gap), Buffer Layer, and “Punch Through”

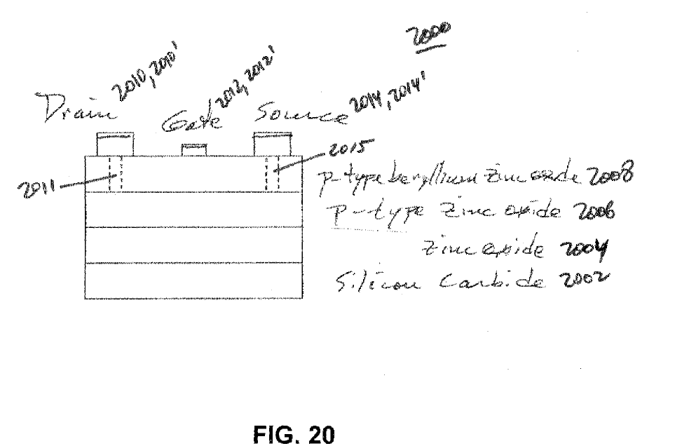

FIG. 20 illustrates another HFET embodiment 2000 of the invention. A first semiconductor layer 2004 of zinc oxide is grown on a single crystal silicon carbide substrate 2002. A second semiconductor layer 2006 of n-type zinc oxide is grown on the first semiconductor layer, and a third semiconductor layer 2008 of p-type beryllium zinc oxide alloy is grown on the second semiconductor layer. The first semiconductor layer serves as a butler layer. The second semiconductor layer serves as the active layer. The energy band gap of the third semiconductor layer is larger than that of the second semiconductor layer. Portions 2015, 2011 of the second layer are removed to expose access sites on the first semiconductor layer to form a source region contact area 2014 and a drain region contact area 2010 that are located on the first semiconductor layer. Electrical leads 2014′, 2010′ are applied to the source and drain contact areas to form ohmic contacts to the first semiconductor layer. A metal gate contact 2012 is formed on the third semiconductor layer located between the source and drain regions, thereby forming a Schottky barrier contact to the third semiconductor layer. An electrical lead 2012′ is applied to the metal gate contact. The device thus formed is an HFET 2000 according to the invention.

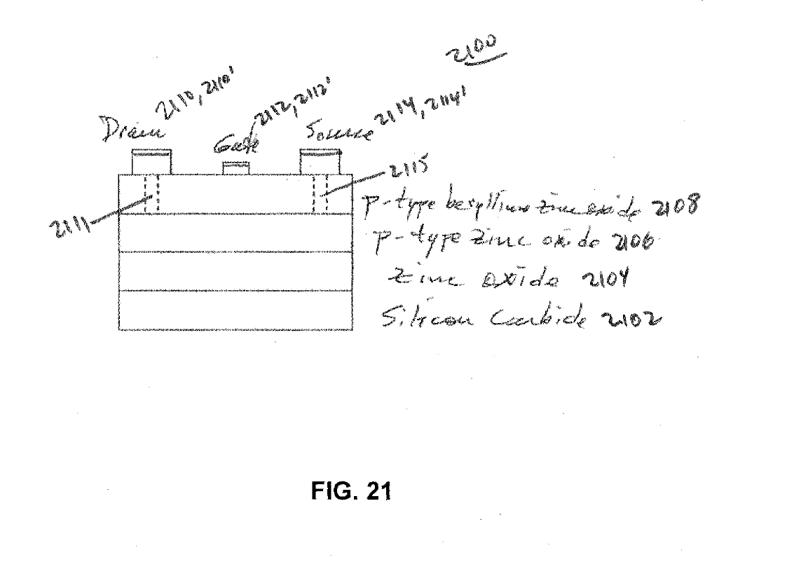

FIG. 21 illustrates another HFET embodiment 2100 of the invention. A first semiconductor layer 2104 of zinc oxide is grown on a single crystal silicon carbide substrate 2102. A second semiconductor layer 2106 of p-type zinc oxide is grown on the first semiconductor layer, and a third semiconductor layer 2108 of p-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. Portions 2115, 2111 of the third layer are removed to expose access sites on the second semiconductor layer to form a source region contact area 2114 and a drain region contact area 2110 that are located on the second semiconductor layer. Electrical leads 2114′, 2110′ are applied to the source and drain contact areas to form ohmic contacts to the second semiconductor layer. A metal gate contact 2112 is formed on the third semiconductor layer located between the source and drain regions, thereby forming a Schottky barrier contact to the third semiconductor layer. An electrical lead 2112′ is applied to the metal gate contact. The device formed is an HFET 2100 according to the invention.

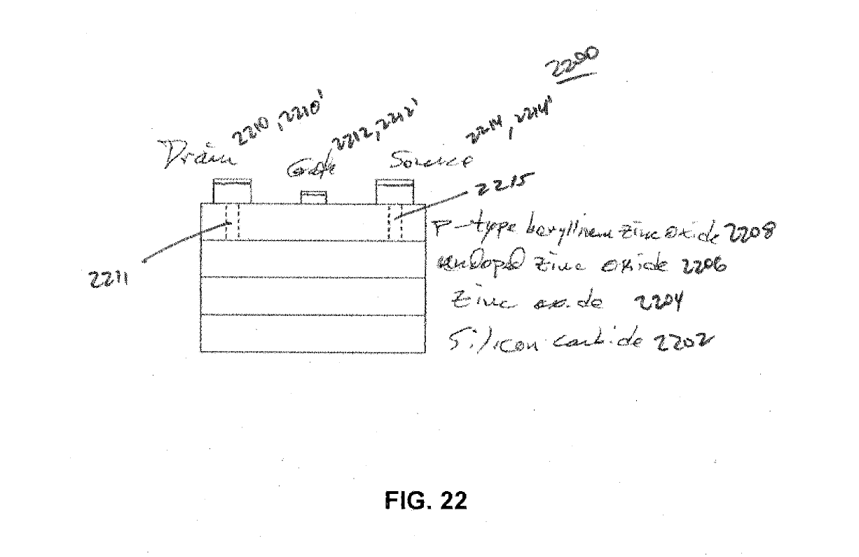

FIG. 22 illustrates another HFET embodiment 2200 of the invention. A first semiconductor layer 2204 of zinc oxide is grown on a single crystal silicon carbide substrate 2202. A second semiconductor layer 2206 of undoped zinc oxide is grown on the first semiconductor layer, and a third semiconductor layer 2208 of p-type beryllium zinc oxide alloy is grown on the second semiconductor layer. The first semiconductor layer serves as a buffer layer. The second semiconductor layer serves as the active layer. The energy band gap of the third semiconductor layer is larger than that of the second semiconductor layer. Portions 2215, 2211 of the third layer are removed to expose access sites on the second semiconductor layer to form a source region contact area 2214 and a drain region contact area 2210 that are located on the second semiconductor layer. Electrical leads 2214′, 2210′ are applied to the source and drain contact areas to form ohmic contacts to the second semiconductor layer. A metal gate contact 2212 is formed on the third semiconductor layer located between the source and drain regions, thereby forming a Schottky barrier contact to the third semiconductor layer. An electrical lead 2212′ is applied to the metal gate contact. The device formed is an HFET 2200 according to the invention.

Example without Buffer Layer

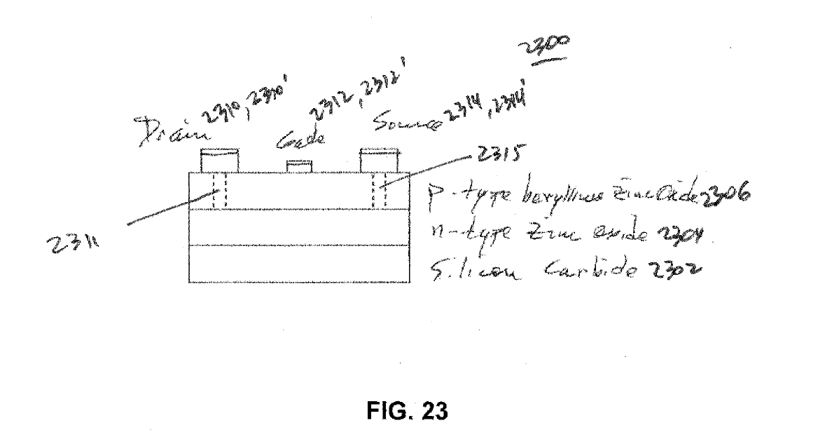

FIG. 23 illustrates another HFET embodiment 2300 of the invention. A first semiconductor layer of n-type zinc oxide 2304 is grown on a single crystal silicon carbide substrate 2302, and a second semiconductor layer 2306 of p-type beryllium zinc oxide alloy is grown on the first semiconductor layer. The first semiconductor layer serves as the active layer. The energy band gap of the second semiconductor layer is larger than that of the first semiconductor layer. Portions 2315, 2311 of the second layer are removed to expose access sites on the first semiconductor layer to form a source region contact area 2314 and a drain region contact area 2310 that are located on the first semiconductor layer. Electrical leads 2314′, 2310′ are applied to the source and drain contact areas to form ohmic contacts to the first semiconductor layer. A metal gate contact 2312 is formed on the second semiconductor layer located between the source and drain regions, thereby forming a Schottky barrier contact to the second semiconductor layer. An electrical lead 2312′ is applied to the metal gate contact. The device formed is an HFET 2300 according to the invention.

Example with GaN Substrate with Thin ZnO Layer and Top Layer of BeZnO

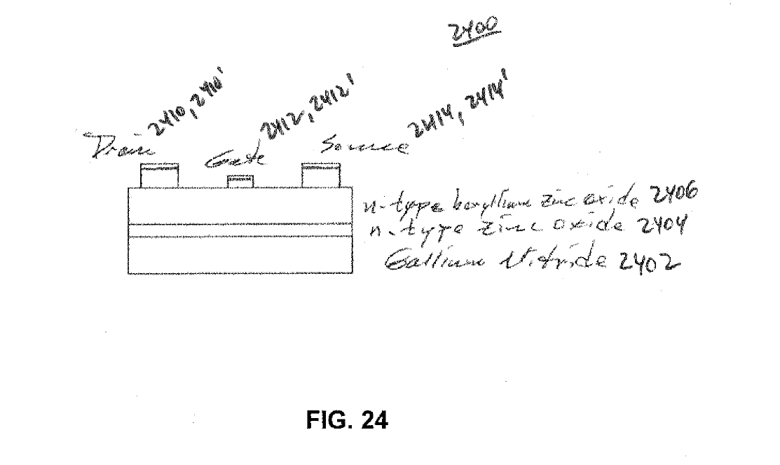

FIG. 24 illustrates another HFET embodiment 2400 of the invention. A first semiconductor layer 2404 of n-type zinc oxide is grown on a gallium nitride substrate 2402, and a second semiconductor layer 2406 of n-type beryllium zinc oxide alloy is grown on the zinc oxide semiconductor layer. The thickness of the zinc oxide semiconductor layer is in the range from about 10 nm to 10,000 nm, and more preferably between about 100 and 1000 nm. The zinc oxide semiconductor layer serves as the active layer. The energy band gap of the n-type beryllium zinc oxide alloy layer is larger than that of the zinc oxide layer. A source region contact area 2414 and a drain region contact area 2410 are located on the n-type beryllium zinc oxide alloy layer. Electrical leads 2414′, 2410′ are applied to the source and drain contact areas to form ohmic contacts. A metal gate contact 2412 is formed on the n-type beryllium zinc oxide alloy layer located between the source and drain regions, thereby forming a Schottky barrier contact to the second semiconductor layer. An electrical lead 2412′ is applied to the metal gate contact. The device formed is an HFET 2400 according to the invention.

Example with GaN Layer on a Substrate, with Thin ZnO Layer, and Top Layer of BeZnO

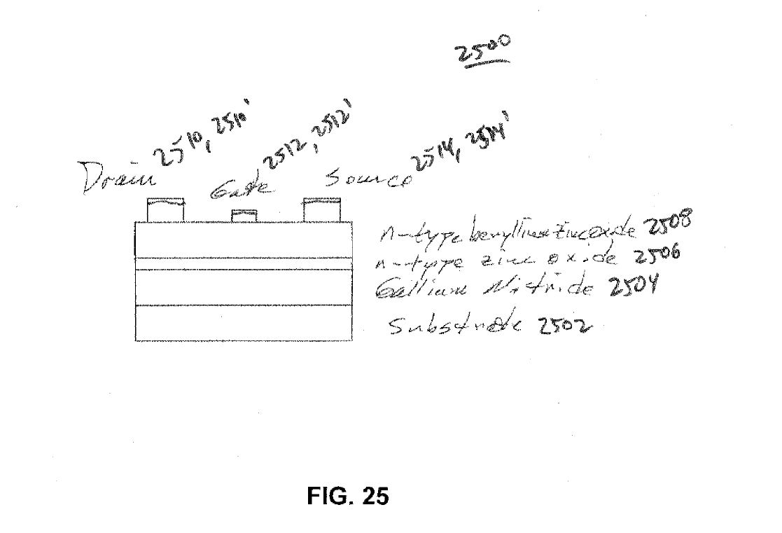

FIG. 25 illustrates another HFET embodiment 2500 of the invention. A first semiconductor layer 2504 of gallium nitride is grown on a substrate 2502. A second semiconductor layer 2506 of n-type zinc oxide is grown on the gallium nitride layer, and a third semiconductor layer 2508 of n-type beryllium zinc oxide alloy is grown on the zinc oxide semiconductor layer. The thickness of the zinc oxide semiconductor layer is in the range from about 10 nm to 10,000 nm, and more preferably between about 100 and 1000 nm. The zinc oxide semiconductor layer serves as the active layer. The energy band gap of the n-type beryllium zinc oxide alloy layer is larger than that of the zinc oxide layer. A source region contact area 2514 and a drain region contact area 2510 are located on the n-type beryllium zinc oxide alloy layer. Electrical leads 2514′, 2510′ are applied to the source and drain contact areas to form ohmic contacts. A metal gate contact 2512 is formed on the n-type beryllium zinc oxide alloy layer located between the source and drain regions, thereby forming a Schottky barrier contact to the second semiconductor layer. An electrical lead 2512′ is applied to the metal gate contact. The material for the substrate is selected from the group comprising, but not limited to, silicon carbide, zinc oxide, gallium nitride, gallium arsenide, sapphire, silicon, glasses, plastics and polymers. The device formed is an HFET 2500 according to the invention.

Additional HFET Examples, BeZnO Layer, n-Type ZnO on Top

Many other embodiments, examples and variations of the present invention are possible, and are within the spirit and scope of the invention as defined in the claims set forth below. By way of further example, in another HFET embodiment of the invention, using a layered structure like that shown in FIG. 1 and others of the attached drawing figures, a first semiconductor layer of zinc oxide is grown on a single crystal silicon carbide substrate. A second semiconductor layer of n-type beryllium zinc oxide alloy is grown on the first semiconductor layer, and a third semiconductor layer of n-type zinc oxide is grown on the second semiconductor layer. The first semiconductor layer serves as a buffer layer. The energy band gap of the second semiconductor layer is larger than that of the third semiconductor layer. The third semiconductor layer serves as the active layer. A source region contact area and a drain region contact area are located on the third layer. An insulating layer region is formed on the third semiconductor layer at a location between the source and drain regions, and a metal gate contact is then formed on the insulating layer region, thereby forming a metal-insulator-semiconductor contact-to the third semiconductor layer. Electrical leads are applied to the source and drain contact areas to form ohmic contacts. An electrical lead is applied to the metal gate contact. The device formed is an HFET.

In another HFET example of the invention, a first semiconductor layer of zinc oxide is grown on a single crystal silicon carbide substrate. A second semiconductor layer of p-type beryllium zinc oxide alloy is grown on the first semiconductor layer, and a third semiconductor layer of n-type zinc oxide is grown on the second semiconductor layer. The first semiconductor layer serves as a buffer layer. The energy band gap of the second semiconductor layer is larger than that of the third semiconductor layer. The third semiconductor layer serves as the active layer. A source region contact area and a drain region contact area are located on the third layer. An insulating layer region is formed on the third semiconductor layer at a location between the source and drain regions, and a metal gate contact is then formed on the insulating layer region, thereby forming a metal-insulator-semiconductor contact to the third semiconductor layer. Electrical leads are applied to the source and drain contact areas to form ohmic contacts. An electrical lead is applied to the metal gate contact. The device formed is an HFET.

In another HFET example of the invention, a first semiconductor layer of zinc oxide is grown on a single crystal silicon carbide substrate. A second semiconductor layer of undoped beryllium zinc oxide alloy is grown on the first semiconductor layer, and a third semiconductor layer of n-type zinc oxide is grown on the second semiconductor layer. The first semiconductor layer serves as a buffer layer. The energy band gap of the second semiconductor layer is larger than that of the third semiconductor layer. The third semiconductor layer serves as the active layer. A source region contact area and a drain region contact area are located on the third layer. An insulating layer region is formed on the third semiconductor layer at a location between the source and drain regions, and a metal gate contact is then formed on the insulating layer region, thereby forming a metal-insulator-semiconductor contact to the third semiconductor layer. Electrical leads are applied to the source and drain contact areas to form ohmic contacts. An electrical lead is applied to the metal gate contact. The device formed is an HFET.

In another HFET example of the invention, a first semiconductor layer of undoped beryllium zinc oxide alloy is grown on a single crystal silicon carbide substrate, and a second semiconductor layer of n-type zinc oxide is grown on the first semiconductor layer. The energy band gap of the first semiconductor layer is larger than that of the second semiconductor layer. The second semiconductor layer serves as the active layer. A source region contact area and a drain region contact area are located on the second layer. An insulating layer region is formed on the third semiconductor layer at a location between the source and drain regions, and a metal gate contact is then formed on the insulating layer region, thereby forming a metal-insulator-semiconductor contact to the second semiconductor layer. Electrical leads are applied to the source and drain contact areas to form ohmic contacts. Au electrical lead is applied to the metal gate contact. The device formed is an HFET.

In still other possible examples, practices, embodiments or aspects of the present invention:

1) The HFET structure can be employ a buffer layer grown on a single crystal substrate.

2) One or more than one layer in an HFET structure can be grown epitaxially.

3) The HFET structure can be prepared with the substrate selected from the group comprising, but not limited to, silicon carbide, zinc oxide, gallium nitride, gallium arsenide, sapphire, silicon, glasses, plastics and polymers.

4) The HFET structure can be prepared with the substrate being undoped and selected from the group comprising, but not limited to, silicon carbide, zinc oxide, gallium nitride, gallium arsenide, sapphire, silicon, glasses, plastics and polymers.

5) The HFET structure can be prepared with the substrate being n-type and selected from the group comprising, but not limited to, silicon carbide, zinc oxide, gallium nitride, gallium arsenide, sapphire, silicon, glasses, plastics and polymers.

6) The HFET structure can be prepared with the substrate being p-type and selected from the group comprising, but not limited to, silicon carbide, zinc oxide, gallium nitride, gallium arsenide, sapphire, silicon, glasses, plastics and polymers.

7) If no buffer layer exists between the substrate and the:first semiconductor n-type layer, then the structure can be prepared with the substrate being n-type, such that the n-type substrate and the n-type first semiconductor layer comprise one entity.

8) If no buffer layer exists between the substrate and the first semiconductor p-type layer, then the structure can be prepared with the substrate being p-type, such that the p-type substrate and the p-type first semiconductor layer comprise one entity.

9) The structure can be prepared with a Schottky metal insulator semiconductor barrier as the gate contact to form a MESFET.

10) The structure can be prepared with a material layer located between the gate contact and the topmost semiconductor layer, wherein the material is an insulator selected from the list comprising, but not limited to, an oxide, an oxide compound, a metal oxide compound, and a dielectric to form a MESFET:

11) The structure can be prepared with a material layer located between the gate contact and the semiconductor layer on which it is deposited to form a junction field effect transistor (NET).

12) To improve ohmic contact the structure can be prepared with an oxide layer with higher electrical conductivity than the topmost semiconductor layer deposited on the source contact area, the drain contact area, or on both the source contact area and the drain contact area prior to applying electrical leads to the source contact area and the drain contact area.

13) At least one oxide layer in the HFET layered structure can be (Group 11, zinc, and oxygen) alloys.

14) At least one oxide layer in the HFET layered structure can be BeZnO, MgZnO, BeMgO, and BcMgZnO alloys.

15) At least one oxide layer in the HFET layered structure can be (zinc, cadmium, selenium, sulfur, and oxygen) alloys.

16) At least one oxide layer in the HFET layered structure can be ZnCdScO, ZnCdSO, ZnCdSSeO, ZnSSeO, ZnSO, and ZnScO alloys.

17) At least one oxide layer in the HFET layered structure can be ZnCdSeO, ZnCdSO, ZnCdSSeO, ZnSSeO, ZnSO, and ZnSeO alloys with incorporation of Be for improvement of lattice matching to one or more other layers or to the substrate.

18) At least one oxide layer in the HFET layered structure can be deposited epitaxially.

19) A buffer layer may be deposited on the substrate selected from the list including, but not limited to, zinc oxide and gallium nitride.

20) The structure can be prepared such that the dopant for the n-type zinc oxide semiconductor layer is at least one element selected from the group consisting of boron, aluminum, gallium, indium, thallium, fluorine, chlorine, bromine and iodine.

21) The structure can be prepared such that the dopant for the p-type zinc oxide semiconductor layer is at least one element selected from the group 1, 11, 5 and 15 elements.

22) The structure can be prepared such that the dopant for the p-type zinc oxide semiconductor layer is selected from the group consisting of arsenic, phosphorus, antimony and nitrogen; or, in a particular aspect of the invention, the dopant for the p-type zinc oxide semiconductor layer may be arsenic alone.

23) The structure can be prepared such that the dopant for the n-type zinc oxide substrate is at least one clement selected from the group consisting of boron, aluminum, gallium, indium, thallium, fluorine, chlorine, bromine and iodine.

24) Alternatively, the structure can be prepared such that the dopant for the p-type zinc oxide substrate is at least one element selected from the group 1, 11, 5 and 15 elements; or an element, or mom than one element, selected from the group consisting of arsenic, phosphorus, antimony and nitrogen; or in one example, arsenic alone.

25) The structure can be prepared such that the dopant for the n-type beryllium zinc oxide alloy semiconductor layer is at least one element selected from the group consisting of boron, aluminum, gallium, indium, thallium, fluorine, chlorine, bromine and iodine.

26) The structure can be prepared such that the dopant for the p-type beryllium zinc oxide alloy semiconductor layer is at least one element selected from the group 1, 11, 5 and 15 elements.

27) The structure can be prepared such that the dopant for the p-type beryllium zinc oxide alloy semiconductor layer is selected from the group consisting of arsenic, phosphorus, antimony and nitrogen; or, in a particular aspect of the invention, the dopant for the p-type zinc oxide semiconductor layer may be arsenic alone.

28) The structure can be prepared such that the dopant for the n-type beryllium zinc oxide alloy substrate is at least one clement selected from the group consisting of boron, aluminum, gallium, indium, thallium, fluorine, chlorine, bromine and iodine.

29) Alternatively, the structure can be prepared such that the dopant for the p-type beryllium zinc oxide alloy substrate is at least one clement selected from the group 1, 11, 5 and 15 elements; or at least one clement selected from the group consisting of arsenic, phosphorus, antimony and nitrogen; or particularly, arsenic alone.

30) Alternatively, the structure can be prepared such that the dopant for a semiconductor layer can be incorporated during growth,

31) Alternatively, the structure can be prepared such that the dopant for a semiconductor layer can be incorporated by process methods comprising, but not limited to, thermal flux, element flux, plasma flux, diffusion, thermal diffusion, and/or ion implantation.

The invention and its technical advantages will be still further illustrated and understood through the following additional examples.

### Further Examples and Description of the Invention

The following discussion provides still further description of various embodiments and examples of the present invention and their characteristics. As noted above, the present invention relates to a layered heterostructure HFET device for improvements in performance of HFET devices, and particularly their high frequency and high power performance.

Although a particular embodiment is next described with respect to a HFET that has a metal semiconductor Schottky barrier gate electrode, it will be understood that the present invention may be practiced with respect to other types of HFETs, such as, for example, MOSFETs, JFETs and other configurations and HFET types, as noted elsewhere in this document.

In one embodiment of this invention, a polished silicon carbide wafer of n-type conductivity cut from a bulk, undoped silicon carbide crystal was used as the substrate. The wafer was placed in a hybrid beam deposition reactor, and heated to approximately 750° C. The pressure was reduced to approximately 1×10⁻⁵ torr and the substrate cleaned with RF oxygen plasma for 30 minutes. The temperature was then lowered to 650° C. and then a first layer of undoped zinc oxide was deposited to a thickness of approximately 0.3 microns on the silicon carbide substrate. Then the temperature was lowered to 550° C. and a second semiconductor layer comprising n-type zinc oxide doped with the clement arsenic was deposited on the first semiconductor layer. The total thickness of the deposited n-type zinc oxide layer doped with gallium was approximately 0.3 micron. Then a third semiconductor layer comprising n-type beryllium zinc oxide alloy doped with the element gallium was deposited on the second semiconductor layer. The total thickness of the deposited n-type beryllium zinc oxide alloy layer doped with gallium was approximately 30 nm.

(A more detailed description of one or more exemplary process(es) useful for depositing a zinc oxide layer, an n-type zinc oxide layer, and a p-type zinc oxide layer, and in particular a p-type zinc oxide layer doped with arsenic and other materials (which may include, for example, beryllium zinc oxide) is set forth, by way of example, in U.S. Pat. No. 6,475,825 (White et al.) and U.S. Pat. No. 6,610,141 (White et al.), and PCT Patent Application Nos. PCT/US03/27143 (Ryu et al.)), PCT/US05/043821 (Ryu et al.) and PCT/US06/011619 (Ryu et al.), each of which is incorporated herein by reference, and made a part of this application, as if set forth in its entirety.)

The wafer with deposited layer's was then removed from the reactor. Ohmic electrical contacts were made to the n-type beryllium zinc oxide alloy layer doped with gallium at spaced and separate source and drain regions, to respectively form a source contact and a drain contact. A metal semiconductor Schottky barrier was formed at the gate contact located between the source contact and drain contact to form a HFET. The ohmic contacts to the drain and were made with Ni and Ti metals. The ratio of the gate width to the gate length of the HFET was about 5, and the gate thickness was very thin, in the range 10 to 150 nm.

A drain voltage V_{D} was applied between the source and drain contacts and a gate voltage V_{G} measured with respect to the drain voltage V_{D} was selected and the HFET was tested for current and voltage characteristics.

The plots of FIGS. 3 and 4, discussed above, show drain current I_{D} versus drain voltage V_{D} characteristics, and drain current I_{D} versus gate voltage V_{G} for an exemplary HFET in accordance with the invention.

Those skilled in the art will readily appreciate that one among other variations, one could fabricate a device with a gate length that is shorter than that used in the embodiments described above; fabricate a device with a gate length of 0.1 microns; apply a voltage between the source contact and drain contact higher than that described above; or apply a voltage between the source contact and drain contact or 10 volts. (The latter two changes would increase the frequency response performance and power performance.)

### CONCLUSION

An HFET structure in accordance with the invention, having the disclosed layered structure, can be used to improve FET performance, and in particular, high frequency and high power performance. A zinc oxide based HFET in accordance with the invention would have many uses in high speed and high power device applications in photonic and electronic areas. Such uses could include, but would not be limited to, applications such as high frequency radar, biomedical imaging, chemical compound identification, molecular identification and structure, sensors, imaging systems, and fundamental studies of atoms, molecules, gases, vapors and solids.

Those skilled in the art will understand that they can also fabricate an HFET of the present invention, in accordance with the disclosure herein, with additional desirable features, such as a shorter length for the gate contact, where such length is measured along the direction of current between the drain contact and the source contact, suitably added insulating layers, and suitably added mesas to help reduce current leakages.

The foregoing examples are set forth by way of illustration and not limitation. Similarly, the terms and expressions used herein are used as terms of description and not of limitation, and there is no intention in the use of such terms and expressions of excluding equivalents of the features shown and described, or portions thereof. Various additions, subtractions, and modifications are possible and are within the spirit and scope of the present invention. Moreover, any one or more features of any embodiment of the invention described herein or otherwise within the scope of the invention may be omitted, or modified, or combined with any one or more other features of any other embodiment of the invention, without departing from the scope of the invention.

1. A heterostructure field effect transistor (HFET) with a layered structure comprising:
a first semiconductor oxide layer; and
a second semiconductor oxide layer grown on the first semiconductor oxide layer, wherein the energy band gap of the second semiconductor layer is larger than that of the first semiconductor layer.

2. A heterostructure field effect transistor (HFET) with a layered structure comprising:
a first semiconductor oxide layer; and
a second semiconductor oxide layer grown on the first semiconductor oxide layer, wherein the energy band gap of the second semiconductor layer is smaller than that of the first semiconductor layer.

3. A heterostructure field effect transistor (HFET) with a layered structure comprising:
a substrate;
a first semiconductor oxide layer grown on the substrate; and
a second semiconductor oxide layer grown on the first semiconductor oxide layer, wherein the energy band gap of the second semiconductor layer is larger than that of the first semiconductor layer.

4. A heterostructure field effect transistor (HFET) with a layered structure comprising:
a substrate;
a first semiconductor oxide layer grown on the substrate; and
a second semiconductor oxide layer grown on the first semiconductor oxide layer, wherein the energy band gap of the second semiconductor layer is smaller than that of the first semiconductor layer.

5. A heterostructure field effect transistor (HFET) with a layered structure comprising:
a first semiconductor oxide layer;
a second semiconductor oxide layer grown on the first semiconductor oxide layer, wherein the energy band gap of the second semiconductor layer is larger than that of the first semiconductor layer;
two ohmic contacts on the second semiconductor oxide layer to form respectively a source contact and a drain contact; and
a gate contact on the second semiconductor layer located between the source contact and the drain contact.

6. A heterostructure field effect transistor (HFET) with a layered structure comprising:
a first semiconductor oxide layer;
a second semiconductor oxide layer grown on the first semiconductor oxide layer, wherein the energy band gap of the second semiconductor layer is smaller than that of the first semiconductor layer;
two ohmic contacts on the second semiconductor oxide layer to form respectively a source contact and a drain contact; and
a gate contact on the second semiconductor layer located between the source contact and the drain contact.

7-40. (canceled)

41. The HFET of claim 1 wherein at least one semiconductor oxide layer comprises an oxide material selected from the list comprising, but not limit to, an oxide comprised of a Group 11 element, ZnO, BeZnO, MgZnO, BeMgZnO, ZnCdScO, ZnCdSO, ZnCdSSeO, ZnSSeO, ZnSO, and ZnSeO.

42. The HFET of claim 1 wherein at least one semiconductor oxide layer comprise Be with one or more of the alloys ZnCdSeO, ZnCdSO, ZnCdSSeO, ZnSSeO, ZnSO, and ZnSeO for improvement of lattice matching between layers.

43. The HFET of claim 1 wherein at least one semiconductor oxide layer comprise Be with one or more of the alloys ZnCdScO, ZnCdSO, ZnCdSSeO, ZnSSeO, ZnSO, and ZnSeO for improvement of lattice matching between a layer and the substrate.

44. The HFET of claim 1 wherein at least one semiconductor oxide layer comprise Mg with BeZnO for improvement of lattice matching between layers.

45. The HFET of claim 1 wherein at least one semiconductor oxide layer comprise Mg with BeZnO for improvement of lattice matching between a layer and the substrate.

46. The HFET of claim 1 wherein a semiconductor layer is epitaxially grown on a layer.

47. The HFET of claim 1 wherein a semiconductor layer is epitaxially grown on the substrate.

48. The HFET of claim 1 wherein a semiconductor layer is epitaxially grown on a buffer layer on the substrate.

49. The HFET of claim 1 wherein a layer comprises an n-type dopant which comprises an clement, or more than one clement, selected from the group consisting of boron, aluminum, gallium, indium, thallium, fluorine, chlorine, bromine and iodine.

50. The HFET of claim 1 wherein a layer comprises a p-type dopant which comprises an clement, or more than one element, selected from the group consisting of Group 1 (IA), Group 11 (IB), Group 5 (VB), and Group 15 (VA) elements.

51. The HFET of claim 1 wherein a layer comprises a p-type dopant that comprises nitrogen.

52. The HFET of claim 1 wherein a layer comprises a p-type dopant that comprises arsenic.

53. The HFET of claim 1 wherein a layer comprises a p-type dopant that comprises phosphorus.

54. The HFET of claim 1 wherein a layer comprises a p-type dopant that comprises antimony.

55-70. (canceled)
